(19) United States
(12) Patent Application Publication
(10) Pub. No.: US 2015/0226836 A1
(43) Pub. Date: Aug. 13, 2015

(54) TRANSCEIVING SURFACE-TREATED METALLIC MEMBER WITHIN TRANSMISSION PATH OF RADAR, AND METHOD OF MANUFACTURING THE SAME

(71) Applicant: Hyundai Motor Company, Seoul (KR)

(72) Inventors: So Jung Shim, Seoul (KR); Seung Chan Hong, Seongnam (KR); Bong Yeon Jeong, Suwon (KR); Byung Kyu Cho, Seoul (KR)

(73) Assignee: Hyundai Motor Company

(21) Appl. No.: 14/551,018

(22) Filed: Nov. 23, 2014

(30) Foreign Application Priority Data
Feb. 13, 2014 (KR) 10-2014-0016679

(51) Int. Cl. G01S 7/02; C23C 16/40; C23C 14/14; C23C 16/50; B60R 19/52; C23C 14/08; C23C 16/06; C23C 14/24

(52) U.S. Cl. CPC G01S 7/02; C23C 16/06; C23C 16/405; C23C 14/24; C23C 16/50; B60R 19/52; C23C 14/083; C23C 14/14; B60R 2019/525; G01S 2007/027

(57) ABSTRACT

Disclosed are a transceiving surface-treated metallic member disposed within a transmission path of a radar, and a method of manufacturing the transceiving surface-treated metallic member. The surface-treated metallic member in the invention provides a more secure transception property within the transmission path of the radar, particularly when it is applied as a smart cruise control (SCC) cover, has an aesthetic appearance, and is manufactured at reduced cost.

### CROSS-REFERENCE TO RELATED APPLICATION

This application claims under 35 U.S.C. §119(a) the benefit of Korean Patent Application No. 10-2014-0016679 filed on Feb. 13, 2014, the entire contents of which are incorporated herein by reference.

### TECHNICAL FIELD

The present invention relates to a transceiving surface-treated metallic member which may be disposed within a transmission path of a radar, and a method of manufacturing the same. In particular, the present invention relates to the surface-treated metallic member providing a more secure transception property within a transmission path of the radar, such as a smart cruise control (SCC) cover of a vehicle. Further, the surface-treated metallic member may improve aesthetic appearance, and may be manufactured at reduced cost.

### BACKGROUND

In a vehicle, a smart cruise system (SCC) refers to a system configured to detect a movement of a front vehicle by a radar mounted at a front side of the vehicle, controlling an engine and a brake, and stably accelerating/decelerating the vehicle when the vehicle changes a lane and avoids the front vehicle, reaccelerating the vehicle to an initially set speed after the front vehicle is removed, and allowing the vehicle to be traveled at a constant speed.

When the smart cruise system is mounted on a vehicle, generally an external member of the vehicle is mounted on an external side of the system, and the external member should not to disturb a radar transception state of the smart cruise system. The radar transception apparatus which is a core of the SCC system is usually installed at a substantially center portion of the front side of the vehicle to provide secure performance thereof. However, a unique emblem of a vehicle manufacturing company is generally disposed on a radiator grill at the front side of the vehicle, and the radiator grill may be plated with a metal to provide for an aesthetic and luxurious appearance—such that the metal parts which have high conductivity and thickness deviation in structures thereof may disrupt uniform radio wave transception of a transmission apparatus of the radar.

Accordingly, to achieve consistent radio wave transception, a separate transmission cover of the radar is provided at a radar unit or a radiator grill. However, since continuous appearance with the radiator grill is not obtained when such a transmission unit is installed, metallic coating has been implemented to provide improved appearance by depositing indium or tin, or by applying a film which may transmit radio wave.

However, indium or tin is substantially expensive material and thus cost of an entire radar unit may increase. Further, and a temperature range during second molding of a molded product may be limited due to a low melting point of such material.

In the related art, a brilliance decorated molded product applied into a beam path of a radar apparatus has been developed. The molded product has a body formed of a transparent resin layer, a tin or tin alloy layer installed on the rear surface of the body, and a designed coated layer installed on the rear surface of the tin or tin alloy layer. The molded product includes tin, alloy of tin and indium, gallium, antimony, bismuth, and the like which provides radio wave transmission and maintains metallic texture, and adopts the tin, but manufacturing cost of the molded product is still substantially high due to the use of the high-cost material and a low melting point thereof.

In the related art, an external component for a vehicle including a proximity member has been developed. The external component is disposed at an external side of an electromagnetic wave transmission member, at a substantial center of an emblem, disposed at a front side of a radar apparatus, and is provided with a chrome plated part reflecting the electromagnetic wave at a front side thereof. Meanwhile, the chrome plated part is installed at a side surface for the purpose of reflection of the electromagnetic wave but may not improve a laser transmission effect. Thus, the chrome plated part may be substantially used for disturbing laser transception and obtaining a reflection effect. In other related arts, a general metallic coating technology related to a radiator grill having a metal plated layer such as chrome has been provided for high-gloss aesthetic appearance. However, the metallic coating technology has been applied for decorative purpose to provide metallic texture, but the transception of the radar has not been considered at all in such technology.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention now provides technical solutions to the aforementioned technical difficulties in the related art. In particular, when a chromium compound is applied with a predetermined thickness or less as a chrome layer to a member disposed within a transmission path of a radar, the member may be manufactured with a metallic surface-treatment securing a laser transception property and an aesthetic appearance thereof at reduced cost.

Accordingly, the present invention provides a surface-treated metallic member having a laser transception property which may be disposed within a transmission path of the radar. In one aspect, the present invention provides a surface-treated metallic member, on which a chromium compound layer or chrome layer is coated. As such, the surface-treated metallic member may have the homogeneous texture as that of a molded product coated with a chrome plating layer, and simultaneously have a laser transception property. In another aspect, the present invention provides a method of manufacturing a surface-treated metallic member having a laser transception property, which may be more easily manufactured into a molded product using cost-effective materials.

In an exemplary embodiment, the present invention provides a transceiving surface-treated metallic member which may be disposed within the transmission path of the radar. The transceiving surface-treated metallic member may include: a chrome layer having a thickness of about 0.01 to 1.0 μm formed on a surface of a plastic molded substrate; and a protection layer formed of a transparent plastic on an outer surface of the chrome layer.

In another exemplary embodiment, the present invention provides a method of manufacturing a transceiving surface-treated metallic member disposed within a transmission path of a radar. The method may include: preparing a plastic molded substrate; forming a chrome layer having a thickness of about 0.01 to 1.0 μm on a surface of the plastic molded substrate by using chromium or a chromium oxide; and forming a protection layer formed of transparent plastic on the chrome layer.

According to the exemplary embodiment of the present invention, in the transceiving surface-treated metallic member disposed within the transmission path of the radar, the chrome layer comprising chromium compounds may be formed on the surface of the plastic molded substrate, and the transparent plastic protection layer is formed, thereby having glazed metallic texture, providing secure transceiving property of the radar, and minimizing reflection and the like which occur in a single coating layer.

Accordingly, cost-efficient manufacturing of the surface-treated metallic member may be obtained while providing the radar transceiving property at reduced cost, having an aesthetic appearance, and maintaining homogeneity with the molded products.

Other aspects and preferred embodiments of the invention are discussed infra.

### BRIEF DESCRIPTION OF THE DRAWINGS

The above and other features of the present invention will now be described in detail with reference to exemplary embodiments thereof illustrated by the accompanying drawings which are given hereinbelow by way of illustration only, and thus are not limitative of the present invention, and wherein:

FIG. 1 illustrates an exemplary cross-sectional structure of an exemplary transceiving surface-treated metallic member disposed within a transmission path of a radar according to an exemplary embodiment of the present invention;

FIG. 2 is an exemplary comparison graph illustrating radio wave transmission attenuation ratio measurement results for a specimen manufactured according to Examples 1 to 3 in the present invention, and the Comparative Example in the related art;

FIG. 3 is an exemplary comparison graph including results of measurement in a change of a radio wave transmission attenuation ratio based on the thickness of each chrome layer of a specimen manufactured according to Example 2 in the present invention; and

FIG. 4 is an exemplary graph measuring and comparing a change in a radio wave transmission attenuation ratio for each content of O₂ gas used in process gas applied to each chrome oxide layer for a specimen manufactured according to Example 4 in the present invention.

Reference numerals set forth in the Drawings include reference to the following elements as further discussed below.
11: Plastic molded product substrate
12: Chrome layer
13: Transparent plastic protection layer

It should be understood that the appended drawings are not necessarily to scale, presenting a somewhat simplified representation of various exemplary features illustrative of the basic principles of the invention. The specific design features of the present invention as disclosed herein, including, for example, specific dimensions, orientations, locations, and shapes will be determined in part by the particular intended application and use environment. In the figures, reference numbers refer to the same or equivalent parts of the present invention throughout the several figures of the drawing.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Hereinafter reference will now be made in detail to various exemplary embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereinafter, an exemplary embodiment of the present invention will be described in detail as follows.

In one aspect, the present invention provides a transceiving surface-treated metallic member disposed within a transmission path of a radar. The transceiving surface-treated metallic member may include: a chrome layer formed on a surface of a plastic molded substrate, and a transparent plastic protection layer formed on the outer surface of the chrome layer, thereby providing glazed metallic texture and a transceiving property of the radar, and minimizing reflection and the like which may occur in a single coating layer.

As used herein, the term “chrome layer” refers to a deposited or plated layer composed of chromium (Cr) or chromium (Cr) compounds.

In addition, a synthetic resin which may be manufactured into a general plastic molded product may be used for the plastic molded substrate. Particularly, a resin selected from a group consisting of: a polycarbonate (PC) resin, an acrylonitrile-butadiene-styrene (ABS) resin and an acrylonitrile-ethylenepropylene rubber-styrene (AES) resin may be used. The plastic molded substrate may be formed of black plastic having a black color, or may be applied with a black paint onto a transparent plastic. Further, the plastic molded substrate may be a single molded product disposed within the transmission path of the radar, or various types of molded products, which may be assembled with another molded product or be a part of other component.

In the exemplary embodiments, the chrome layer having a thickness of about 0.01 to 1 μm may be formed on the plastic molded substrate. Although the metallic texture may be provided in the chrome layer, the chrome layer may particularly have a transceiving property within the transmission path of the radar according to the invention. In general, the chrome layer is known as a metal layer having a tendency of reflecting electromagnetic waves. Accordingly, in the present invention, when the chrome layer is applied, radio wave transmission generally needs to be available at a vehicle allowed frequency of about 76 to 77 GHz, and further, attenuation ratio of the radio wave transmission needs to be minimized during an operation of a smart cruise control (SCC) system.

According to exemplary embodiments of the present invention, when a thickness of the chrome layer is greater than about 1.0 μm, the attenuation ratio may substantially increase, so that a transceiving property may sharply deteriorate, and thus the effects of the present invention may not be obtained. When the thickness of the chrome layer is less than about 0.01 μm, the chrome layer may not be applied sufficiently, or the chrome layer may not be generated, and further a crack may or a product defect may be generated during a process of application of the molded product. Accordingly, the thickness of the chrome layer may be in a particular range of about 0.01 to 0.3 μm considering the radio wave transmission attenuation ratio and the like. The chrome layer may be made of chromium, a chromium oxide, or a chromium nitride. Chromium oxide may be particularly used for the chrome layer.

According to the exemplary embodiments of the present invention, the protection layer made of a transparent plastic may be formed on the outer surface of the chrome layer. A conventional transparent plastic synthetic resin may be applied as the protection layer without limitation, and a polycarbonate resin, an acryl resin, or a polyolefin resin may be particularly used. The protection layer may be formed by bonding the substrate and the protection layer in the form of double injection after the chrome layer is formed on the substrate.

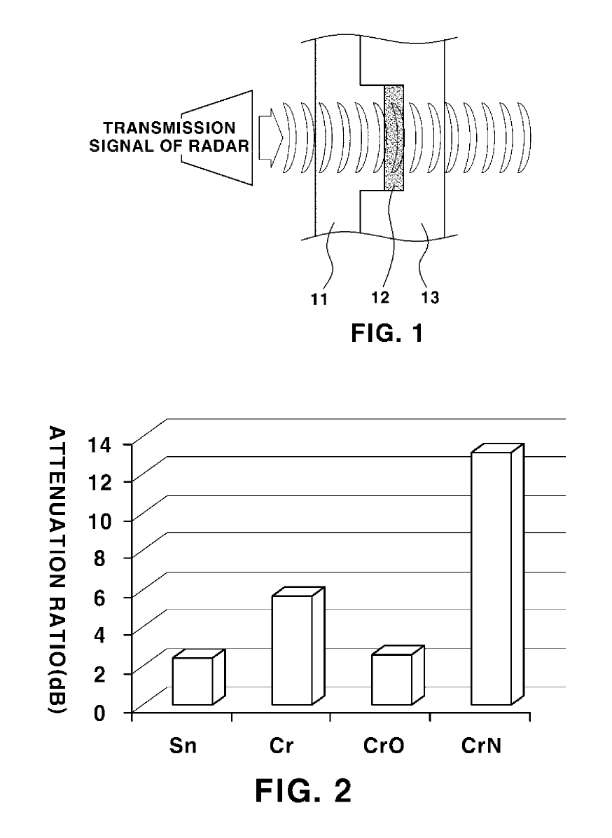

A cross-sectional structure of an exemplary transceiving surface-treated metallic member which may be disposed within the transmission path of the radar according to an exemplary embodiment of the present invention is schematically illustrated in FIG. 1. As shown in FIG. 1, the chrome layer 12 and the transparent plastic protection layer 13 are sequentially formed on the plastic molded substrate 11 to provide the secure transceiving transmission property for the transmission of the radar.

In other aspect, an exemplary method of manufacturing the transceiving surface-treated metallic member which may be disposed within the transmission path of the radar will be described below.

The manufacturing method of the transceiving surface-treated metallic member within the transmission path of the radar may include: preparing a plastic molded substrate; forming a chrome layer having a thickness of about 0.01 to 1.0 μm by using chromium, chromium nitride, or chromium oxide on a surface of the plastic molded substrate; and forming a protection layer formed of a transparent plastic on the chrome layer.

In the exemplary embodiments of the present invention, in the preparing of the plastic molded product substrate, the plastic molded substrate may be prepared by molding. The plastic molded substrate may be manufactured to have a desired shape by using a conventional method and the synthetic resin, and the like as generally known in the art. When the molded product is molded with the transparent plastic, the molded product may also be coated with a black paint if necessary.

According to the exemplary embodiments of the present invention, in the forming of the chrome layer by using the chromium, the chromium nitride, or the chromium oxide on the plastic molded substrate, a thin coat layer having a nanoscale thickness, such as about 0.01 to 1.0 μm of the chrome layer, may not be obtained by controlling a thickness of the chrome layer through a plating coating method. Accordingly, the chrome layer may be formed by a vacuum deposition method, particularly by physical vapor deposition (PVD) or plasma assisted chemical vapor deposition (PACVD) process.

Further, in the operation of forming the chrome layer, a chromium target and process gas such as argon (Ar), oxygen (O₂), or nitrogen (N₂) may be used. The chrome layer may be coated and formed by changing a vacuum state into a plasma state by using Ar gas, activating Ar ions to collide with a surface, and then removing an organic material from the surface.

In particular, the coating of the chrome layer may be performed so that the thickness of the chrome layer may be of about 0.01 to 1.0 μm, or 0.3 μm or less, or particularly of about 0.2 μm or less by using the chromium target and the process gas. When the chrome layer is formed of pure chromium (Cr), the chrome layer may be coated and formed by using Ar gas, as the process gas and the Cr target. When chrome layer is formed of chromium nitride (CrN), the chrome layer may be formed by using Ar gas and N₂ gas as reactive gas and the Cr target. Further, when the chrome layer is made of a chromium oxide (CrO), the chrome layer may be formed by using Ar gas and O₂ gas as reactive gas and the Cr target.

Moreover, the chrome layer may be made of the chrome oxide, since the chromium oxide has the greatest attenuation ratio at a specific radio wave region of about 76 to 77 GHz among the Cr compounds. The chromium oxide may have a particular radio wave transmission property based on a flow rate of O₂ gas as a reactive gas used in the process of forming the chrome layer, thereby providing a difference in degree of the attenuation ratio.

Accordingly, since the attenuation ratio is changed based on the increase in a ratio of O₂ gas when the chrome layer is formed of chromium oxide, O₂ gas as reactive gas may be included in an amount of about 1 to 60 volume %, of about 6 to 50 volume %, or particularly of about 10 to 30 volume % of the entire process gas. When a content of O₂ gas is substantially reduced, the radio wave transmission attenuation ratio by the formed chrome layer may increase substantially. When a content of O₂ gas substantially increase, the attenuation ratio may not change, and rather a reaction condition may deteriorate. When the chrome layer is formed of the chromium nitride, the content of N₂ gas may have the similar tendency to that of O₂ gas.

After the chrome layer is formed through the aforementioned process, an operation of forming the protection layer formed of a transparent plastic on the chrome layer may be performed. In particular, the protection layer may be formed by preparing a synthetic resin in a form of a film, but without limitation. Further, according to an exemplary embodiment, the protection layer may be formed by forming and bonding the substrate and the protection layer by double injection after the chrome layer is formed on the substrate. The chrome layer may be formed by depositing on a rear surface of the transparent plastic or a front surface of a black plastic, such as ABS and AES, and then bonding the transparent plastic and the black plastic by double injection.

The transceiving surface-treated metallic member disposed within the transmission path of the radar manufactured according to exemplary embodiments of the present invention may be applied as a component for a vehicle. Exemplary component for the vehicle may be an outside decoration component such as a radiator grill, a radiator grill, and the like.

Accordingly, in another aspect, the present invention provides a component for a vehicle including the aforementioned transceiving surface-treated metallic member disposed within the transmission path of the radar.

The transceiving surface-treated metallic member which may be disposed within the transmission path of the radar manufactured according to the exemplary embodiments of the present invention may impart glazed metal texture and provide the secure radio wave transmission property by applying an amorphous chrome layer. Particularly, the glazed metal texture may be needed to be implemented in the plastic substrate, so that the properties such as a radio wave transmission property for the chrome layer may be obtained by forming a thickness within the predetermined range through the deposition at a room temperature. As such, the surface-treated member satisfying the most important transceiving property of the radar of a transmissive cover may be manufactured by implementing the amorphous metal layer.

The amorphous metallic chrome layer used in the present invention costs significantly less than tin, indium, and the like. Distinctively from the general alloy, the amorphous metallic chrome layer has irregular arrangement of molecules and has a fine structure like liquid without crystalline structure, thereby having an advantageous dielectric characteristic applicable as a coating layer which is required to have a laser transceiving property in the present invention. Further, according to certain exemplary embodiments of the present invention, the chrome layer may be directly deposited on the plastic molded substrate without forming a primer layer, thereby decreasing refraction, reflection, and the like of the radio waves through the minimized intermediate layer. In addition, a melting point of the material may be greater than that of existing indium or tin, a temperature limitation which may occur when using indium or tin due to a low melting point during the second molding of the molded product may be eliminated.

Accordingly, the transceiving surface-treated metallic member which may be disposed within the transmission path of the radar according to various exemplary embodiments of the present invention may provide the more secure transceiving property within the transmission path of the radar. For example, when the SCC cover including the transceiving surface-treated metallic member of the invention is applied to a vehicle and the like, aesthetic appearance may be obtained and the SCC cover may be applicable at low cost.

Hereinafter, the present invention will be described in detail with reference to the Examples, but is not limited by the Examples.

### Example 1

A substrate was prepared by depositing a Cr compound (pure chromium) on a flat plate specimen, which had a size of about 150 mm×150 mm, was formed of a PC material, and had a thickness of about 2.9 mm. The deposition of the Cr compound used a Cr target and process gas by using general deposition coating equipment, such that, a vacuum state was changed into a plasma state by using Ar gas, and the surface of the substrate was cleaned by applying bias to activate Ar ions to collide with the surface. The chrome layer was formed by coating a Cr layer with a thickness of about 0.2 μm by using the Cr target and the Ar gas.

Subsequently, the specimen was manufactured by double injecting the flat plate formed of the PC material on which the chrome layer is formed and a transparent PC protection layer material.

### Example 2

Example 2 was manufactured as described in Example 1, but the chrome layer was formed of chromium oxide (CrO). The chrome layers were formed with various thicknesses by increasing by about 0.1 μm from about 0.1 to about 1.0 μm by using Ar and O₂ gas and the Cr target. The content of O₂ gas in process gas was about 23 volume % of entire process gas.

### Example 3

Example 3 was manufactured as described in Example 1, but the chrome layer was formed of a chromium nitride (CrN). The chrome layer was formed with a thickness of about 0.2 μm by using Ar and N₂ gas and the Cr target. The content of N₂ in process gas was about 23 volume % of entire process gas.

### Example 4

Example 4 was manufactured as described in Example 2, but the specimens were manufactured by forming the chrome layer with a thickness of about 0.2 μm by varying the content of O₂ in process gas, respectively, such as about 3%, about 5%, about 7%, about 9%, about 13%, and about 23% (volume %) during the process of forming the chrome layer.

### Comparative Example

The Comparative Example was manufactured as described above in Example 1, but an tin (Sn) layer was formed instead of the chrome layer.

### Experimental Example 1

A radio wave transmission attenuation ratio was measured with the specimens having a thickness of about 0.2 μm of the chrome layer or the Sn layer manufactured according to Examples 1 to 3, and the Comparative Example, and the measurement was evaluated through a 2-way attenuation ratio measuring apparatus. A frequency for the evaluation was about 76 to about 77 GHz which is an allowed frequency of a vehicle.

Changes in the attenuation ratio of the tin (Sn) layer of the Comparative Example, and the chrome (Cr, CrO, CrN) layers of Examples 1 to 3 were compared and illustrated in the graph of FIG. 2.

As can be seen in FIG. 2, the attenuation ratio increases in an order of CrO<Cr<CrN, and the attenuation ratio for the specimen including the chrome layer adopting the chromium oxide (CrO) in the Example 2 has the lowest value, and the attenuation ratio for the specimen adopting the chrome nitride (CrN) is substantially high.

### Experimental Example 2

Changes in a radio wave transmission attenuation ratio at various thicknesses of the chrome layers for the specimens manufactured in Example 2 were measured.

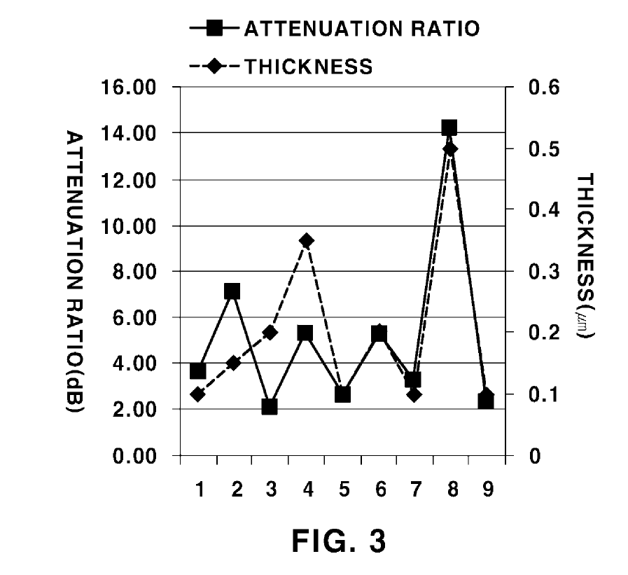

FIG. 3 illustrates the results from the attenuation ratio for each thickness condition. When the thickness of the chrome layer is about 0.2 μm or less, the transmission attenuation ratio is the lowest.

### Experimental Example 3

Changes in a radio wave transmission attenuation ratio for each content of O₂ gas in the process gas during the deposition and the forming of the chrome layers for the specimens manufactured in Example 4 were measured.

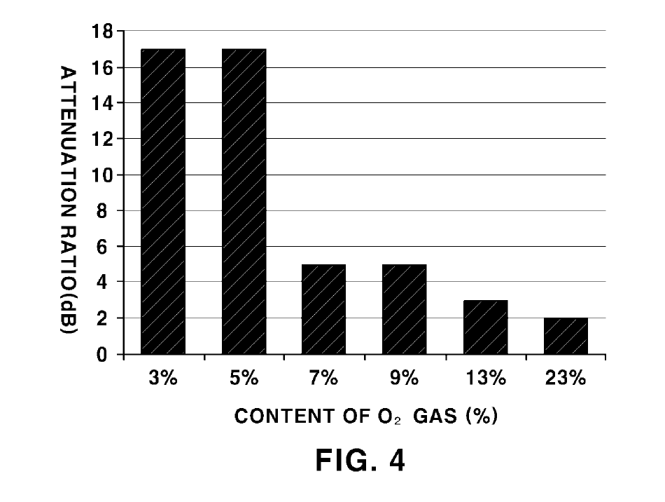

FIG. 4 illustrates the results from the attenuation ratio for each O₂ gas content condition in FIG. 4. When the content of O₂ gas is about 6 volume % or greater, the transmission attenuation ratio is substantially small.

### Experimental Example 4

An adhesive force of the coating layer for the specimen manufactured according to Example 2 was evaluated. The adhesive force was evaluated by forming a lattice by drawing 11 vertical lines and 11 horizontal lines on a surface of the flat specimen with an interval of about 1 mm by using a sharp knife, thereby generating 100 lattices with 1 mm² in a space of 10 mm×10 mm. Subsequently, a tape test was performed according to the method suggested in the ISO 2409 (Paints and Varnishes Cross Cut Test).

As a result of the test of the adhesive force of the chrome layer, all of the specimens were 0/100 and excellent without a defect.

In various exemplary embodiments, the chrome layer may be formed on the surface of the plastic molded substrate, and the transparent plastic protection layer may be formed thereon, so that the transceiving surface-treated metallic member which may be disposed within the transmission path of the radar may have a glazed metallic texture and also provide the secure transceiving property of the radar, thereby being used for facilities or equipment in industries to which various SCC systems are applied.

Further, the transceiving surface-treated metallic member which may be disposed within the transmission path of the radar according to the present invention may be applicable as a component for a vehicle, and may be particularly applied to an external decoration component and the like which may be mounted on a radiator grill.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A transceiving surface-treated metallic member, comprising:
a chrome layer having a thickness of about 0.01 to 1.0 μm and formed on a surface of a plastic molded substrate; and
a protection layer formed of a transparent plastic on an outer surface of the chrome layer.

2. The transceiving surface-treated metallic member of claim 1, wherein the plastic molded product substrate is selected from a group consisting of: a polycarbonate (PC) resin, an acrylonitrile-butadiene-styrene (ABS) resin, and an acrylonitrile-ethylenepropylene rubber-styrene (AES) resin.

3. The transceiving surface-treated metallic member of claim 1, wherein the chrome layer is formed of chromium or a chromium oxide.

4. The transceiving surface-treated metallic member of claim 1, wherein the protection layer is formed of a polycarbonate resin, an acryl resin, or a polyolefin resin.

5. The transceiving surface-treated metallic member of claim 1, wherein the protection layer is bonded to the plastic molded substrate in a form of double injection after the chrome layer is formed.

6. The transceiving surface-treated metallic member of claim 1 is disposed within a transmission path of a radar in a vehicle.

7. A method of manufacturing a transceiving surface-treated metallic member, comprising:
preparing a plastic molded substrate;
forming a chrome layer having a thickness of about 0.01 to 1.0 μm on a surface of the substrate by using chromium or a chromium oxide; and
forming a protection layer formed of transparent plastic on the chrome layer.

8. The method of claim 7, wherein the chrome layer is formed by a vacuum deposition method.

9. The method of claim 7, wherein the chrome layer is formed by changing a vacuum state into a plasma state using argon (Ar) gas and removing an organic material on the surface by activating Ar ions to collide with the surface.

10. The method of claim 7, wherein when the chrome layer is formed of a chromium oxide, oxygen O₂ gas is used in an amount of about 1 to 60 volume % of entire process gas.

11. The method of claim 7, wherein the forming of the protection layer includes bonding the substrate and the protection layer by double injection after the chrome layer is formed on the substrate.

12. A component for a vehicle including the transceiving surface-treated metallic member of claim 1 which is disposed within a transmission path of a radar.

13. The component of claim 12, wherein the component is a radiator grill or an external decoration component of the radiator grill.
